(19) United States
(12) Patent Application Publication
(10) Pub. No.: US 2012/0250287 A1
(43) Pub. Date: Oct. 4, 2012

(54) Electrical box with disconnect

(76) Inventor: Joti Projkovski, Naples, FL (US)

(21) Appl. No.: 13/065,714

(22) Filed: Mar. 29, 2011

(51) Int. Cl. H05K 7/00; H01H 9/02

(52) U.S. Cl. 361/837; 174/53

(57) ABSTRACT

The invention is directed to providing a switch in an electrical box having one or more electrical devices located therein. The switch is connected within the circuit between a fuse panel and any one of those devices. Thereby, when trouble-shooting any of the electrical devices, the switch will only disconnect that device or devices without disturbing other electrical appliances or stations that happen to be in operation in the same circuit that is being serviced by the same fuse panel.

### BACKGROUND OF THE INVENTION

The inventive concept is directed to a breaker switch that is located between a wall switch or a gang of wall switches or electrical outlets and a fuse panel. The reason for this that in many circuits in a room are several rooms where there are other appliances in operation, such as a computer, or are in an “on” or an operational position and if any of the wall devices need to be serviced or a trouble shooting is taking place, they cannot be cut off by breaking the respective fuse to discontinue a certain circuit. The legend in many circuit breaker or fuse panels is oftentimes missing, is incorrect or illegible. It is dangerous for a lay person or an expert to troubleshoot a wall switch or a gang of wall switches while the electric power is on.

### BRIEF DESCRIPTION OF THE INVENTION

Because of the above described problems, the inventive concept contemplates to place a breaker switch between the wall switch or switches or electrical outlets, hereafter called electrical devices, and the fuse panel so that whenever work or trouble shooting needs to be undertaken, the respective circuit can be discontinued between the wall switch and the fuse panel without disturbing other remote switches or outlets that happen to be in the same circuit. This inventive concept also comes in handy where there are electrical outlets in a children's room. As a safety measure it may be advisable to disconnect any of the outlets by activating the breaker switch. The inventive concept has a simple solution by placing a cut-off switch in the electrical box wherein certain electrical devices are located. The switch is placed between the main hot wire coming into the box and the wire leading to the electrical devices and from there to the circuit breaker or fuse panel.

### BRIEF DESCRIPTION OF THE DRAWINGS

FIG. 1 is a schematic of the wiring when a switch is added to the interior of an electrical box.

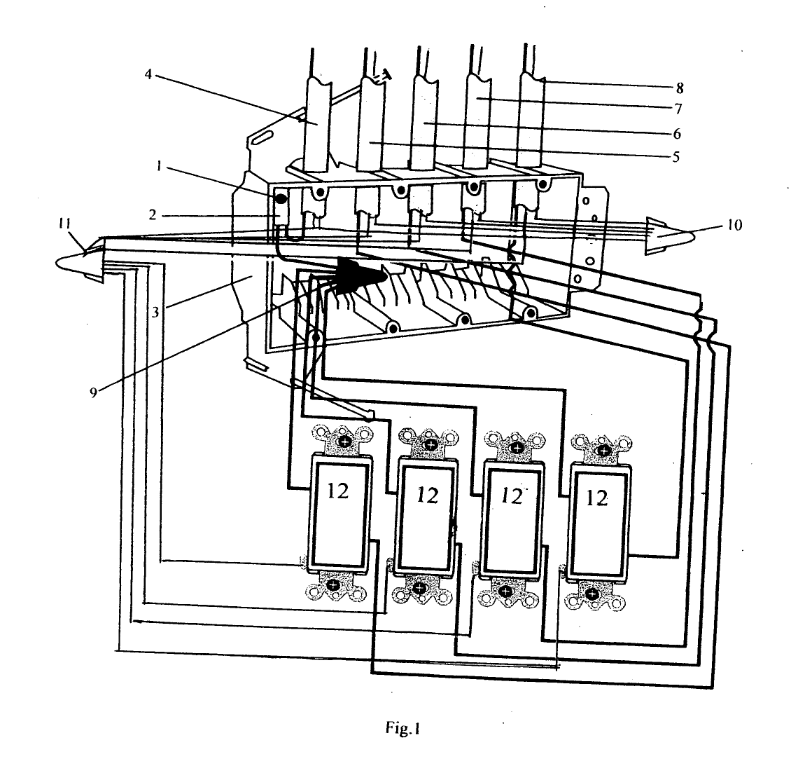

The schematic circuitry of FIG. 1 shows the breaker switch 1 in switch housing 2. The switch 1 is located in an upper left corner of the electrical box 3. The location is a matter of choice. The disconnect switch 1 receives its hot power through a line 4 coming from the electrical fuse panel. The line coming from the other side of the switch 1 is spliced by the splicer nut 9 into one or more wires leading to one side of the electrical devices 12. The circuits 5, 6, 7 and 8 are coming from the electrical devices 12, such as electrical switches or electrical outlets, etc., which are located and mounted in the electrical box 3 and continue into one or more lines or circuits 5, 6, 7, and 8 leading away from the one or more switches to remote circuits such as ceiling fans or light fixtures. It is to be understood that the electrical devices 12 can be restricted to one switch or a gang of switches and that ganged devices 12 can be a combination of switches and electrical outlets. The neutral or ground wires are spliced to the neutral wire coming from the fuse panel by way of the splicer nut 10.

It is to be understood that while a certain form of the invention is illustrated, it is not to be limited to the specific form or arrangement of parts described and shown. It will be apparent to those skilled in the art that various changes may be made without departing from the scope of the invention and the invention is not To be considered limited to what is shown and described in the specification and the drawings.

What I claim is:

1. An electrical box having at least one electrical device located therein and having a hot wire side connected to a fuse panel, the improvement comprising: a switch being located in said electrical box and being connected to said fuse panel by way of hot wire side.

2. The electrical box of claim 1, wherein there are a multiple of said electrical devices located in said electrical box.

3. The electrical box of claim 2, wherein said multiple of electrical devices are switches.

4. The electrical box of claim 2, wherein said multiple of electrical devices is a combination of said breaker and electrical outlets.

5. An electric circuit consisting of a fuse panel and at least one electrical device located in an electrical box, the improvement comprising; a switch is located in said box and within a circuit between said electrical box and said fuse panel.
